(19) United States
(12) Patent Application Publication
(10) Pub. No.: US 2026/0005146 A1
(43) Pub. Date: Jan. 1, 2026

(54) SEMICONDUCTOR DEVICES HAVING INTERCONNECTION STRUCTURES THEREIN WITH ENHANCED METAL ALLOYS

(71) Applicant: Samsung Electronics Co., Ltd., Suwon-si (KR)

(72) Inventors: Hase Naoki, Suwon-si (KR); Inji Lee, Suwon-si (KR); Keiichiro Jinushi, Tokyo (JP); Takanobu Matsumura, Tokyo (JP); Gyu-Hee Park, Suwon-si (KR); Sanghyun Park, Suwon-si (KR); Eunyoung Lee, Suwon-si (KR)

(73) Assignees: Samsung Electronics Co., Ltd., Suwon-si (KR); Furuya Metal Co., Ltd., Tokyo (JP)

(21) Appl. No.: 19/173,919

(22) Filed: Apr. 9, 2025

(30) Foreign Application Priority Data
Jun. 28, 2024 (KR) 10-2024-0085129

(51) Int. Cl. H01L 23/532; H01L 23/522; H01L 23/528; H10B 12/00; H10D 30/00; H10D 62/10; H10D 62/13

(52) U.S. Cl. CPC H01L 23/53261; H01L 23/5226; H01L 23/5283; H01L 23/53257; H10B 12/485; H10D 30/503; H10D 30/506; H10D 62/121; H10D 62/151; H10B 12/315

(57) ABSTRACT

A semiconductor device includes a substrate, and an interconnection layer on the substrate. The interconnection layer includes an interconnection structure having a first interconnection line therein that includes a metal alloy containing a single phase of ruthenium and a non-ruthenium first element having a concentration in a range from greater than 0 at % to 40 at % in the metal alloy. In the event the first element is molybdenum, the concentration of the first element in the metal alloy may range from 0.1 at % to 30 at %; but, in the event the first element is tungsten, the concentration of the first element in the metal alloy may range from 0.1 at % to 40 at %.

### REFERENCE TO PRIORITY APPLICATION

This U.S. non-provisional patent application claims priority under 35 U.S.C. § 119 to Korean Patent Application No. 10-2024-0085129, filed Jun. 28, 2024, the disclosure of which is hereby incorporated herein by reference.

### BACKGROUND

To meet the increasing demand for smaller, thinner, and lighter electronic products, there is active research into metal elements and alloys that can be applied to a thin film with a thickness of 10 nm or less. In particular, as the size of semiconductor devices decrease, the need for metallic materials is growing, because metallic material typically has a shorter electron mean free path (eMFP), low resistance, and small surface roughness.

### SUMMARY

An embodiment of the inventive concept provides a semiconductor device including a metal line, which is formed of a metallic material with low resistivity and generally small roughness.

According to an embodiment of the inventive concept, a semiconductor device may include a substrate including a transistor and an interconnection layer disposed on the substrate. The interconnection layer may include an interconnection structure including a first interconnection line. The first interconnection line may include ruthenium and a metal alloy, which contains a first element different from the ruthenium. A composition ratio of the first element in the metal alloy may be greater than 0 at % and less than 40 at %, and the metal alloy may have a single phase of the ruthenium.

According to an embodiment of the inventive concept, a semiconductor device may include a substrate including a transistor and an interconnection layer disposed on the substrate. The interconnection layer may include an interconnection structure and a first via on the interconnection structure. The interconnection structure may include a first interconnection line, and the first interconnection line may include ruthenium and a first metal alloy, which contains a first element different from the ruthenium. A composition ratio of the first element in the first metal alloy may be greater than 0 at % and less than 40 at %, and the first metal alloy may have a single phase of the ruthenium.

According to an embodiment of the inventive concept, a semiconductor device may include a substrate including a transistor and an interconnection layer disposed on the substrate. The interconnection layer may include an interconnection structure including a plurality of first interconnection lines, and each of the first interconnection lines may be extended in a first direction parallel to the substrate. The first interconnection lines may include interconnection lines, which have a pitch ranging from 1 nm to 60 nm in a second direction that is parallel to the substrate and is perpendicular to the first direction. The first interconnection lines may include ruthenium and a metal alloy, which contains a first element different from the ruthenium. A composition ratio of the first element in the metal alloy may be greater than 0 at % and less than 40 at %, and the metal alloy may have a single phase of the ruthenium.

### BRIEF DESCRIPTION OF THE DRAWINGS

FIG. 1 is a plan view illustrating a semiconductor device according to an embodiment of the inventive concept.

FIG. 2 is a sectional view taken along a line A-A′ of FIG. 1.

FIGS. 3A to 3D are schematic diagrams illustrating an interconnection structure according to an embodiment of the inventive concept.

FIG. 4A is a graph showing roughness measured from metal alloys according to some embodiments of the inventive concept and pure metals according to the comparative example.

FIG. 4B is a graph showing the roughness reduction ratios of the metal alloys according to some embodiments of the inventive concept, relative to a pure ruthenium according to the comparative example.

FIG. 5A is a graph showing resistivity values measured from the metal alloys according to some embodiments of the inventive concept and the pure metals according to the comparative example.

FIG. 5B is a graph showing the resistivity values measured from the pure tungsten and the metal alloys according to some embodiments of the inventive concept, plotted against the composition ratio of the first element in the metal alloy.

FIG. 6 is a plan view illustrating a semiconductor device according to an embodiment of the inventive concept.

FIG. 7A is a sectional view taken along a line A-A′ of FIG. 6.

FIG. 7B is a sectional view taken along a line B-B′ of FIG. 6.

FIG. 7C is a sectional view taken along a line C-C′ of FIG. 6.

FIG. 7D is a sectional view taken along a line D-D′ of FIG. 6.

FIG. 8 is an enlarged sectional view illustrating a portion ‘A’ of FIG. 7A.

FIGS. 9A to 9D are diagrams schematically illustrating a method of fabricating an interconnection structure, according to an embodiment of the inventive concept.

FIG. 10 is a block diagram illustrating a semiconductor memory device according to an embodiment of the inventive concept.

FIG. 11 is a plan view corresponding to a portion ‘P1’ of FIG. 10.

FIG. 12A is a sectional view taken along a line A-A′ of FIG. 11.

FIG. 12B is a sectional view taken along a line B-B′ of FIG. 11.

FIG. 12C is a sectional view taken along a line C-C′ of FIG. 11.

FIG. 13 is an enlarged view illustrating a portion ‘P2’ of FIG. 12A.

FIGS. 14A to 14C are diagrams schematically illustrating a method of fabricating an interconnection structure, according to an embodiment of the inventive concept.

### DETAILED DESCRIPTION

Example embodiments of the inventive concepts will now be described more fully with reference to the accompanying drawings, in which example embodiments are shown.

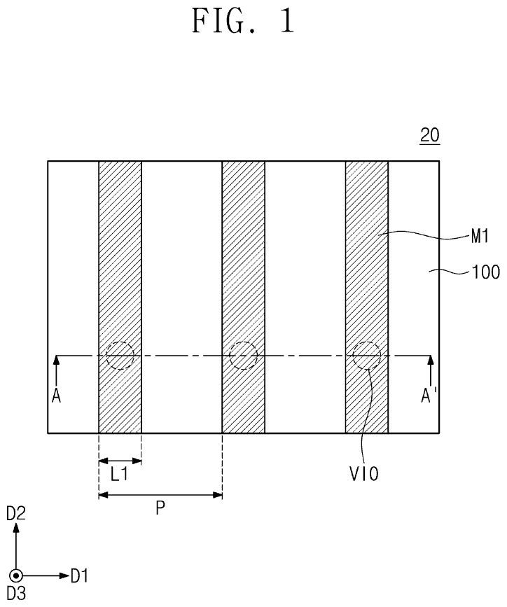

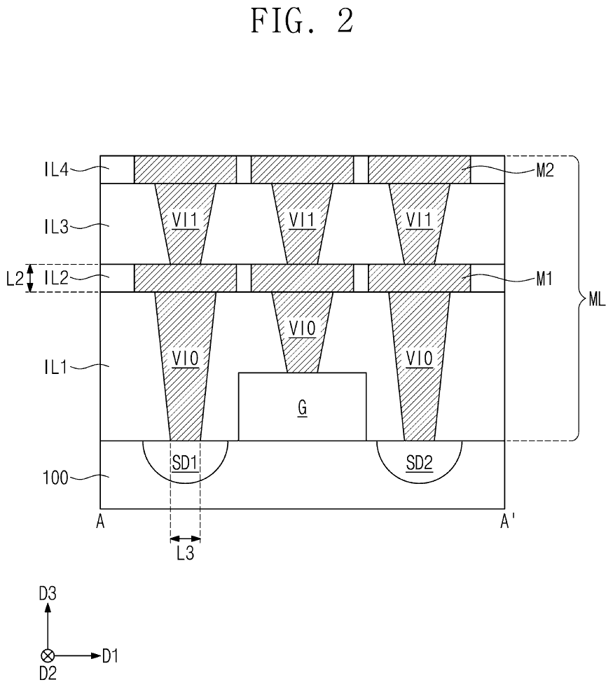

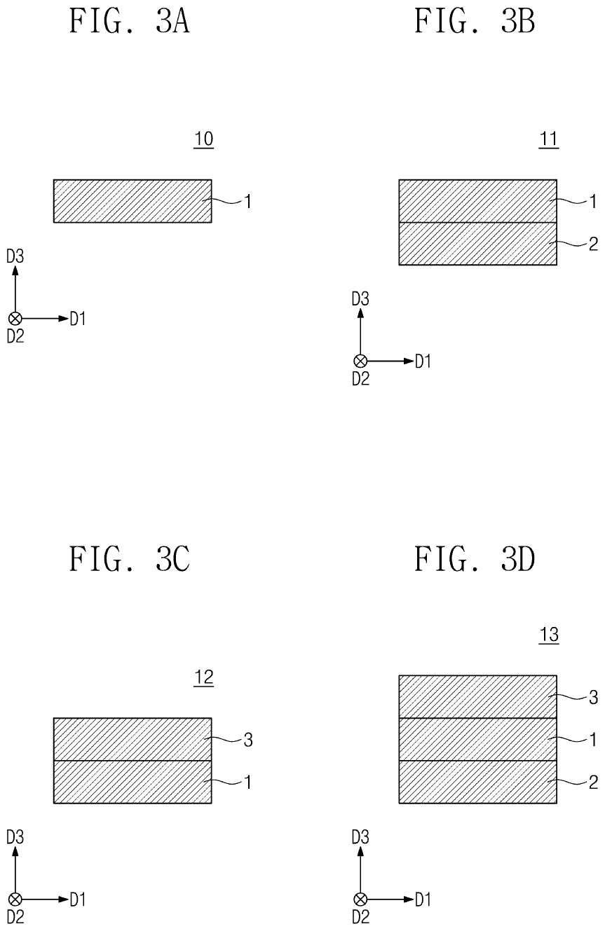

FIG. 1 is a plan view illustrating a semiconductor device according to an embodiment of the inventive concept. FIG. 2 is a sectional view taken along a line A-A′ of FIG. 1, and FIGS. 3A to 3D are schematic diagrams illustrating an interconnection structure according to an embodiment of the inventive concept. Referring to FIGS. 1 and 2, a semiconductor device 20 may include a substrate 100 including a transistor and an interconnection layer ML disposed on the substrate 100. As shown, the transistor may include a first source/drain pattern SD1, a gate electrode G, and a second source/drain pattern SD2. The first and second source/drain patterns SD1 and SD2 may be impurity regions of a first conductivity type (e.g., n-type) or a second conductivity type (e.g., p-type). A shape of a channel is not limited to that of a planar transistor (shown in FIGS. 1 and 2); for example, the transistor may be a fin field-effect transistor (FINFET) or a multi-bridge channel field-effect transistor (MBCFET) having a non-planar channel(s).

As shown in FIG. 2, the interconnection layer ML may include a first interconnection structure M1, a second interconnection structure M2, a first via VI0, a second via VI1, a first insulating layer IL1, a second insulating layer IL2, a third insulating layer IL3, and a fourth insulating layer IL4, which are provided on the substrate 100. The first interconnection structure M1 may include a plurality of interconnection lines, each of which is extended in a second direction D2 parallel to the substrate 100. The first interconnection structure M1 may have a linewidth L1 in a first direction D1, which is parallel to the substrate 100 and perpendicular to the second direction D2. The first interconnection structure M1 may have a thickness L2 in a third direction D3 that is perpendicular to the substrate 100. The first interconnection structure M1 may have a pitch P in the first direction D1.

The second interconnection structure M2 may be provided on the substrate 100. The first interconnection structure M1 may be interposed between the second interconnection structure M2 and the substrate 100. Similar to the first interconnection structure M1, the second interconnection structure M2 may be extended in the second direction D2 and may have a linewidth and a pitch in the first direction D1 and a thickness in the third direction D3.

The first via VI0 may be provided on the substrate 100 and may be interposed between the first interconnection structure M1 and the substrate 100. The first via VI0 may have a diameter L3 on a plane parallel to the substrate 100. The first via VI0 may connect the first interconnection structure M1 to at least one of the gate electrode G, the first and second source/drain patterns SD1 and SD2. The first via VI0 may be in contact with one of the interconnection lines of the first interconnection structure M1. The first via VI0 may be in contact with the gate electrode G or at least one of the first and second source/drain patterns SD1 and SD2.

The second via VI1 may be provided on the substrate 100 and may be interposed between the first interconnection structure M1 and the second interconnection structure M2. The second via VI1 may have a diameter on a plane parallel to the substrate 100. The second via VI1 may be in contact with one of interconnection lines in the first interconnection structure M1. The second via VI1 may be in contact with one of interconnection lines in the second interconnection structure M2.

The first, second, third, and fourth insulating layers IL1, IL2, IL3, and IL4 may be provided on the substrate 100. The first insulating layer IL1 may cover a top surface of the substrate 100 and a side surface of the first via VI0. The second insulating layer IL2 may be provided on the first insulating layer IL1 and may cover a top surface of the first insulating layer IL1 and a side surface of the first interconnection structure M1. The third insulating layer IL3 may be provided on the second insulating layer IL2 and may cover a top surface of the second insulating layer IL2 and a side surface of the second via VI1. The fourth insulating layer IL4 may be provided on the third insulating layer IL3 and may cover a top surface of the third insulating layer IL3 and a side surface of the second interconnection structure M2. Although not shown, additional interconnection structures (e.g., M3, M4, . . . ), additional vias (e.g., VI2, VI3, . . . ), and additional insulating layers (e.g., IL5, IL6, . . . ) may be provided on a top surface of the fourth insulating layer IL4 and a top surface of the second interconnection structure M2.

The semiconductor device 20 may include an interconnection structure whose linewidth is greater than 0 nm and less than 200 nm, ranges from 0.1 nm to 100 nm, ranges from 1 nm to 40 nm, ranges from 3 nm to 30 nm, or ranges from 5 nm to 10 nm. In an embodiment, a linewidth L1 of the first interconnection structure M1 and/or a linewidth of the second interconnection structure M2 may be greater than 0 nm and less than 200 nm, may range from 0.1 nm to 100 nm, may range from 1 nm to 40 nm, may range from 3 nm to 30 nm, or may range from 5 nm to 10 nm.

The semiconductor device 20 may include an interconnection structure whose thickness is greater than 0 nm and less than 200 nm, ranges from 0.1 nm to 100 nm, ranges from 1 nm to 40 nm, ranges from 3 nm to 30 nm, or ranges from 5 nm to 10 nm. In an embodiment, a thickness L2 of the first interconnection structure M1 and/or a thickness of the second interconnection structure M2 may be greater than 0 nm or less than 200 nm, may range from 0.1 nm to 100 nm, may range from 1 nm to 40 nm, may range from 3 nm to 30 nm, or may range from 5 nm to 10 nm.

The semiconductor device 20 may include an interconnection structure whose pitch is greater than 0 nm and less than 500 nm, ranges from 0.1 nm to 400 nm, ranges from 1 nm to 300 nm, ranges from 3 nm to 200 nm, ranges from 5 nm to 100 nm, ranges from 10 nm to 60 nm, or ranges from 15 nm to 30 nm. In an embodiment, the pitch P of the first interconnection structure M1 and/or a pitch of the second interconnection structure M2 may be greater than 0 nm and less than 500 nm, may range from 0.1 nm to 400 nm, may range from 1 nm to 300 nm, may range from 3 nm to 200 nm, may range from 5 nm to 100 nm, may range from 10 nm to 60 nm, or may range from 15 nm to 30 nm.

In an embodiment, the semiconductor device 20 may further include a capacitor (not shown). The capacitor may be electrically connected to the first source/drain pattern SD1, and the first interconnection structure M1 may be electrically connected to the second source/drain pattern SD2 through the first via VI0.

Referring to FIGS. 1 and 2 in conjunction with FIGS. 3A to 3D, a semiconductor device 20 may include one of interconnection structures 10, 11, 12, and 13 according to some embodiments of the inventive concept. At least one of the first and second interconnection structures M1 and M2 may be one of the interconnection structures 10, 11, 12, and 13.

Referring to FIG. 3A, the interconnection structure 10 may include a first interconnection line 1. The first interconnection line 1 may include ruthenium (Ru) and a metal alloy, which contains a first element different from ruthenium (Ru). In an embodiment, the first element may be molybdenum (Mo) or tungsten (W). In the metal alloy, a concentration (and possibly also a composition ratio) of the first element may be greater than 0 at % and less than 40 at %, may range from 0.1 at % to 30 at %, may range from 0.5 at % to 25 at %, may range from 1 at % to 20 at %, may range from 3 at % to 15 at %, or may range from 5 at % to 12 at %. The metal alloy may have a single phase of ruthenium, and may not have a multi-phase, in which a phase of ruthenium and a phase of molybdenum are mixed, or in which a phase of ruthenium and a phase of tungsten are mixed. Furthermore, the metal alloy may not have a single phase of molybdenum or a single phase of tungsten.

Referring to FIG. 3B, the interconnection structure 11 may further include a barrier pattern 2. The barrier pattern 2 may be provided on the first interconnection line 1. The barrier pattern 2 may include at least one of metal, metal nitride, and metal silicide. For example, the barrier pattern 2 may include at least one of TiN, TiSi, TiSiN, WSi, WSiN, Ti, Ta, W, Co, or CoSi. A thickness of the barrier pattern 2 may be greater than 0 nm and equal to or less than 20 nm or may range from 0.1 nm to 15 nm, from 1 nm to 10 nm, or from 3 nm to 5 nm. The thickness of the barrier pattern 2 may be smaller than the thickness of the first interconnection line 1. Referring to FIG. 3B in conjunction with FIGS. 1 and 2, the barrier pattern 2 may be interposed between the first interconnection line 1 and the substrate 100.

Referring to FIG. 3C, the interconnection structure 12 may include the first interconnection line 1 and a second interconnection line 3 provided on the first interconnection line 1. The second interconnection line 3 may include ruthenium (Ru). A composition ratio of the ruthenium in the second interconnection line 3 may be greater than a composition ratio of the ruthenium in the first interconnection line 1. For example, the composition ratio of the ruthenium in the second interconnection line 3 may be greater than or equal to 99 at %. Referring to FIG. 3C in conjunction with FIGS. 1 and 2, the first interconnection line 1 may be interposed between the second interconnection line 3 and the substrate 100.

Next, referring to FIG. 3D, the interconnection structure 13 may include the first interconnection line 1, the barrier pattern 2, and the second interconnection line 3. The first interconnection line 1 may be interposed between the second interconnection line 3 and the barrier pattern 2.

Referring to FIGS. 1 and 2 in conjunction with FIGS. 3A to 3D, the semiconductor device 20 may include a via disposed on one of the interconnection structures 10, 11, 12, and 13. The via may be the first via VI0 and/or the second via VI1. In an embodiment, the via, which is disposed on one of the interconnection structures 10, 11, 12, and 13, may include ruthenium (Ru) and a metal alloy, which contains a first element different from ruthenium (Ru). In an embodiment, the first element may be molybdenum (Mo) or tungsten (W). In the metal alloy, a composition ratio of the first element may be greater than 0 at % and less than 40 at %, may range from 0.1 at % to 30 at %, may range from 0.5 at % to 25 at %, may range from 1 at % to 20 at %, may range from 3 at % to 15 at %, or may range from 5 at % to 12 at %.

The metal alloy may have a phase of ruthenium. The metal alloy may have a single phase of ruthenium. The metal alloy may not have a multi-phase, in which a phase of ruthenium and a phase of molybdenum are mixed, or in which a phase of ruthenium and a phase of tungsten are mixed. The metal alloy may not have a single phase of molybdenum or a single phase of tungsten. In an embodiment, the metal alloy in the via may be the same as the metal alloy of the first interconnection line 1, which is used in one of the interconnection structures 10, 11, 12, and 13.

In another embodiment, a via, which is disposed on one of the interconnection structures 10, 11, 12, and 13, may include at least one of Mo, W, or Co. A minimum value of a diameter of the via may be greater than 0 nm and less than 200 nm, may range from 0.1 nm to 100 nm, may range from 1 nm to 40 nm, may range from 3 nm to 30 nm, and may range from 5 nm to 10 nm. In an embodiment, the minimum value of the diameter L3 of the first via VI0 and/or the minimum value of the diameter of the second via VI1 may be greater than 0 nm or less than 200 nm, may range from 0.1 nm to 100 nm, may range from 1 nm to 40 nm, may range from 3 nm to 30 nm, or may range from 5 nm to 10 nm.

### Formation of Thin Metal Films and Measurement of Roughness And Resistivity

A SiO₂-containing insulating layer was formed on a substrate including pure silicon (Si). Thin films of the metal alloys according to some embodiments of the inventive concept and pure metals according to a comparative example, were formed on the insulating layer. Ruthenium-molybdenum alloys and ruthenium-tungsten alloys were used as the metal alloys. The samples were prepared by varying the composition ratio of molybdenum or tungsten and adjusting the thickness of the films, while unchanging other conditions. Roughness (Ra) of each thin film was measured through an atomic force microscopy (AFM) analysis. In addition, resistivity (p) of each thin film was measured.

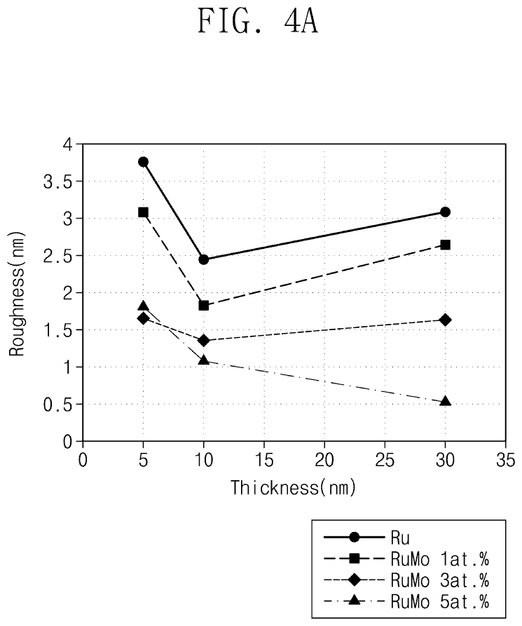

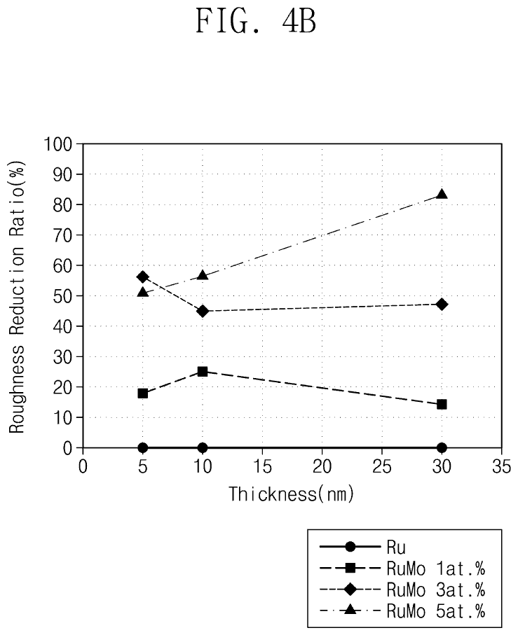

FIG. 4A is a graph showing roughness measured from the metal alloys according to some embodiments of the inventive concept and the pure metals according to the comparative example. In detail, the roughness data in FIG. 4A were measured from 5 nm, 10 nm, and 30 nm thick films made of pure ruthenium and ruthenium-molybdenum alloys (with molybdenum contents of 1%, 3%, and 5%). In addition, FIG. 4B is a graph showing the roughness reduction ratios of the metal alloys according to some embodiments of the inventive concept, relative to the pure ruthenium according to the comparative example. In detail, FIG. 4B shows the roughness reduction ratio of the ruthenium-molybdenum alloy films compared to the pure ruthenium film with the same thickness.

Moreover, Table 1 shows the roughness values measured from 30 nm thick films made of ruthenium, molybdenum, tungsten, a ruthenium-molybdenum alloy (with a molybdenum content of 15 at %), and a ruthenium-tungsten alloy (with a tungsten content of 21 at %).

TABLE 1

| Sample | Roughness (Rₐ, nm) |
|---|---|
| Ru | 3.07 |
| Mo | 0.55 |
| W | 0.57 |
| RuMo 15 at % | 0.23 |
| RuW 21 at % | 0.26 |

Referring to Table 1, the ruthenium had low resistivity but high roughness, while the tungsten and the molybdenum had low roughness but high resistivity compared to the ruthenium. This shows that if the tungsten or molybdenum atoms are added in the ruthenium-based film, the film can have lower resistivity and lower roughness and be an alloy suitable for use as a fine interconnection structure.

Referring to FIGS. 4A and 4B, even when the content of molybdenum in the RuMo alloy is low (e.g., 1 at %), the experiment shows that the roughness of the film can be improved by 10% or more compared with the pure ruthenium. Moreover, as shown by FIG. 4A and Table 1, the higher the content of molybdenum or tungsten in RuMo or RuW alloy, the greater the improvement of the roughness. Referring to FIG. 4A, the 30 nm thick films made of RuMo or RuW alloy having a molybdenum or tungsten content of 5 at % or higher had better roughness than the 30 nm thick films made of pure molybdenum or tungsten.

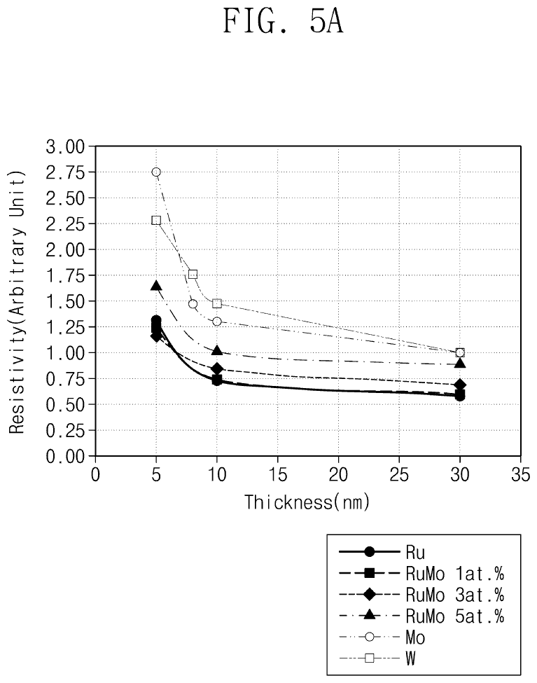

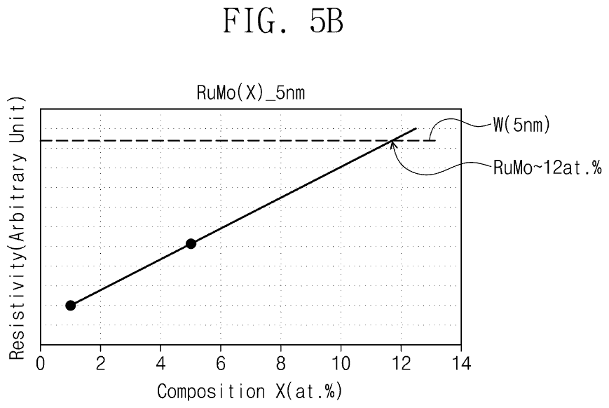

FIG. 5A is a graph showing resistivity values measured from the metal alloys according to some embodiments of the inventive concept and the pure metals according to the comparative example. In detail, the resistivity data in FIG. 5A were measured from 5 nm, 8 nm, 10 nm, and 30 nm thick films made of pure ruthenium, pure molybdenum, pure tungsten, and ruthenium-molybdenum alloys (with molybdenum contents of 1 at %, 3 at %, and 5 at %). Referring to FIG. 5A, the RuMo alloys had resistivity lower than the pure molybdenum or tungsten, regardless of their thickness (e.g., from 5 nm to 30 nm). In addition, the alloy with the molybdenum content of 5 at % had a slightly greater resistivity than the pure ruthenium, and the RuMo alloy with the molybdenum content of 1 at % or 3 at % had substantially the same resistivity as the pure ruthenium.

FIG. 5B is a graph showing the resistivity values measured from the pure tungsten and the metal alloys according to some embodiments of the inventive concept, plotted against the composition ratio of the first element in the metal alloy. In detail, FIG. 5B shows the resistivity values measured from 5 nm thick films made of pure tungsten and ruthenium-molybdenum alloys (with molybdenum contents 1 at %, 3 at %, and 5 at %), and in FIG. 5B, the x-axis represents the content of molybdenum.

Referring to FIGS. 5A and 5B, it may be possible to calculate a molybdenum content (at %) of a 5 nm thick RuMo alloy film at which the RuMo alloy film has a resistance value lower than that of a 5 nm thick pure tungsten film. For example, FIGS. 5A and 5B shows that, when the film of RuMo or RuW alloy had the Mo or W content of 12 at % or lower, it had better resistivity than the film of pure molybdenum or tungsten.

Table 2 shows the resistivity ratios of ρ₁₀/ρ₃₀ measured from samples made of pure ruthenium and ruthenium-molybdenum alloys (with molybdenum contents of 1 at %, 3 at %, and 5 at %), where ρ₃₀ is the resistivity of 30 nm thick samples and ρ₁₀ is the resistivity of 10 nm thick samples.

TABLE 2

| | Ratio (ρ₁₀/ρ₃₀) |
|---|---|
| Ru | 1.23 |
| RuMo 1 at % | 1.23 |
| RuMo 3 at % | 1.23 |
| RuMo 5 at % | 1.15 |

Table 3 shows the resistivity ratios of ρ₅/ρ₁₀ measured from samples made of pure ruthenium and ruthenium-molybdenum alloys (with molybdenum contents of 1 at %, 3 at %, and 5 at %), where ρ₁₀ is the resistivity of 10 nm thick samples and ρ₅ is the resistivity of 5 nm thick samples.

TABLE 3

| | Ratio (ρ₅/ρ₁₀) |
|---|---|
| Ru | 1.78 |
| RuMo 1 at % | 1.63 |
| RuMo 3 at % | 1.36 |
| RuMo 5 at % | 1.59 |

Referring to Tables 2 and 3, even when the molybdenum content in the RuMo alloy samples was low, an increase in resistivity caused by the reduction in thickness of the film was lower in the RuMo alloy samples than, or equal to, in the pure Ru samples.

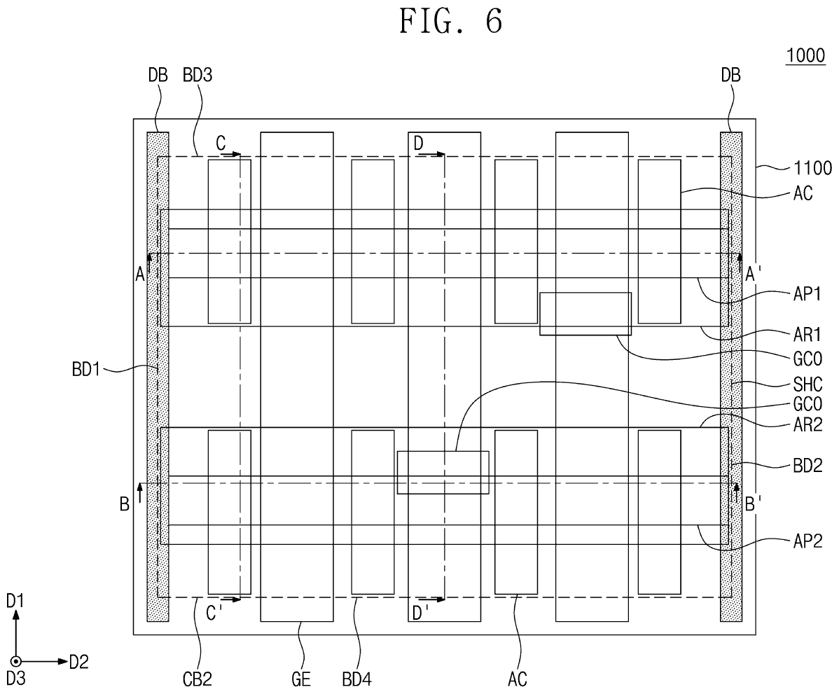

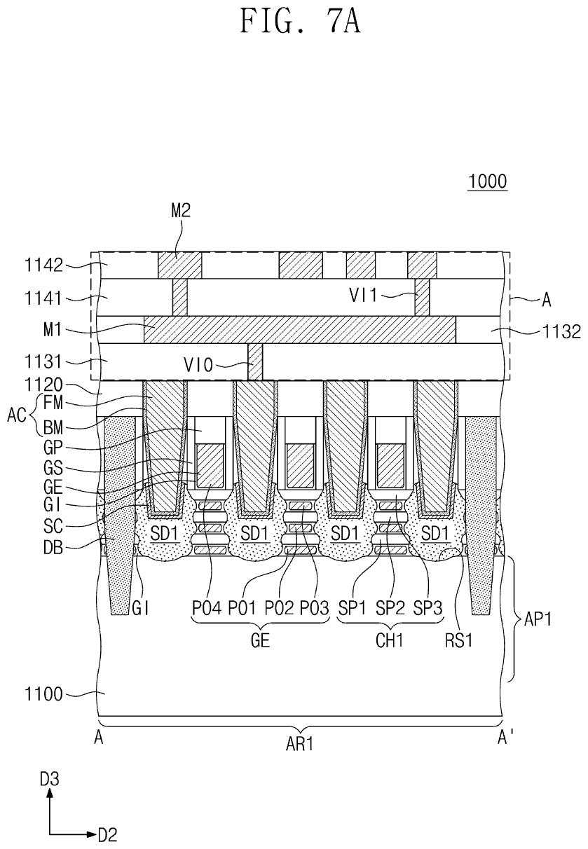

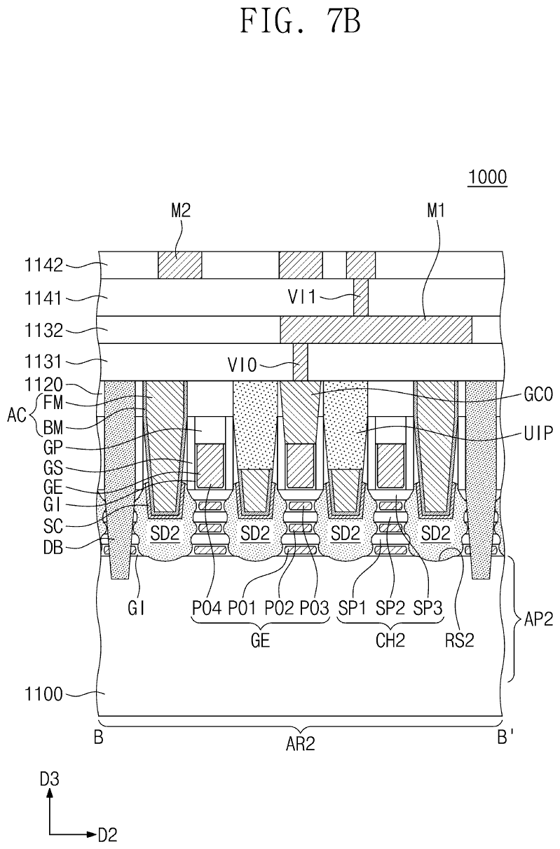

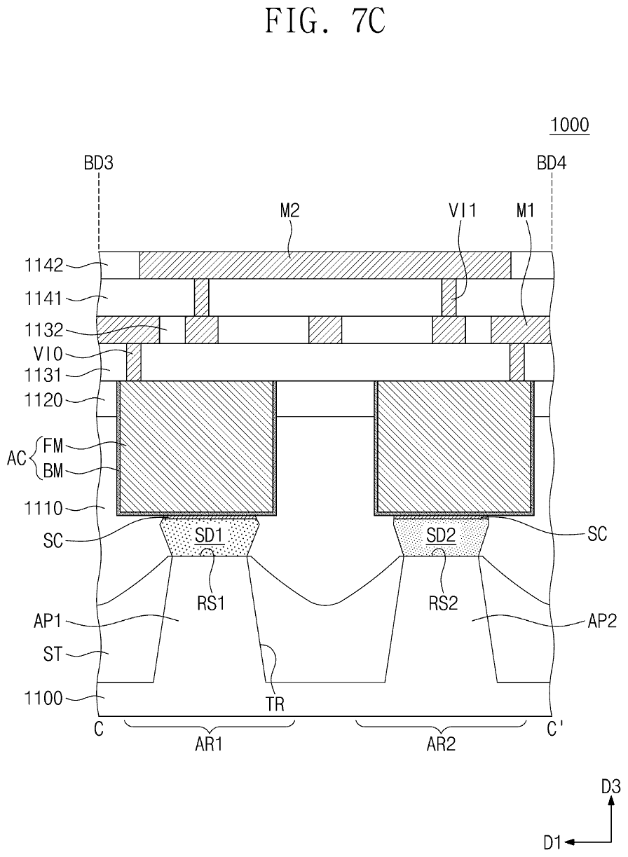

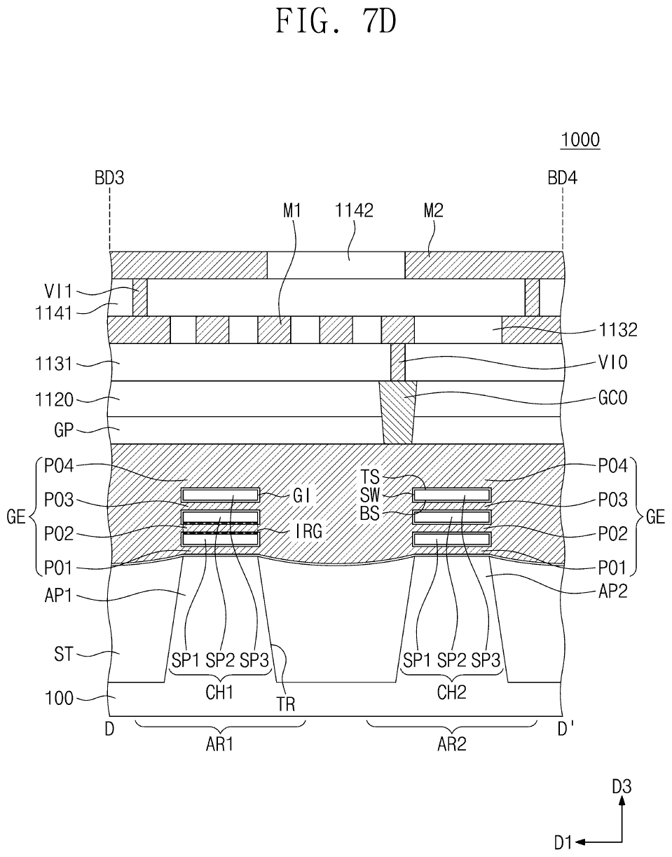

FIG. 6 is a plan view illustrating a semiconductor device according to an embodiment of the inventive concept. FIG. 7A is a sectional view taken along a line A-A′ of FIG. 6. FIG. 7B is a sectional view taken along a line B-B′ of FIG. 6. FIG. 7C is a sectional view taken along a line C-C′ of FIG. 6. FIG. 7D is a sectional view taken along a line D-D′ of FIG. 6. Referring to FIGS. 6 and 7A to 7D, a single height cell SHC may be provided on a substrate 1100. Logic transistors constituting a logic circuit may be disposed on the single height cell SHC. The substrate 1100 may be a semiconductor substrate that is formed of or includes silicon, germanium, silicon germanium, a compound semiconductor material, or the like. In an embodiment, the substrate 1100 may be a silicon wafer.

The substrate 1100 may include a first active region AR1 and a second active region AR2. Each of the first and second active regions AR1 and AR2 may be extended in the second direction D2. In an embodiment, the first active region AR1 may be an NMOSFET region, and the second active region AR2 may be a PMOSFET region.

A first active pattern AP1 and a second active pattern AP2 may be defined by a trench TR, which is formed in an upper portion of the substrate 1100. The first active pattern AP1 may be provided on the first active region AR1, and the second active pattern AP2 may be provided on the second active region AR2. The first and second active patterns AP1 and AP2 may be extended in the second direction D2. The first and second active patterns AP1 and AP2 may be vertically protruding portions of the substrate 1100.

A device isolation layer ST may be provided on the substrate 1100. The device isolation layer ST may fill the trench TR. The device isolation layer ST may include a silicon oxide layer. The device isolation layer ST may not cover first and second channel patterns CH1 and CH2, which will be described below.

A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3, which are sequentially stacked. The first to the third semiconductor patterns SP1, SP2, and SP3 may be spaced apart from each other in a direction (e.g., the third direction D3) that is perpendicular to a top surface of the substrate 1100. Each of the first to the third semiconductor patterns SP1, SP2, and SP3 may be formed of or include silicon (Si), germanium (Ge), or silicon-germanium (SiGe). For example, each of the first to the third semiconductor patterns SP1, SP2, and SP3 may include crystalline silicon.

A plurality of first source/drain patterns SD1 may be provided on the first active pattern AP1. A plurality of first recesses RS1 may be formed in an upper portion of the first active pattern AP1. The first source/drain patterns SD1 may be provided in the first recesses RS1, respectively. The first source/drain patterns SD1 may be impurity regions of a first conductivity type (e.g., n-type). The first channel pattern CH1 may be interposed between a pair of the first source/drain patterns SD1. In other words, the pair of the first source/drain patterns SD1 may be connected to each other through the first to the third semiconductor patterns SP1, SP2, and SP3 stacked.

A plurality of second source/drain patterns SD2 may be provided on the second active pattern AP2. A plurality of second recesses RS2 may be formed in an upper portion of the second active pattern AP2. The second source/drain patterns SD2 may be provided in the second recesses RS2, respectively. The second source/drain patterns SD2 may be impurity regions of a second conductivity type (e.g., p-type). The second channel pattern CH2 may be interposed between a pair of the second source/drain patterns SD2. In other words, the pair of the second source/drain patterns SD2 may be connected to each other through the first to the third semiconductor patterns SP1, SP2, and SP3 stacked.

Gate electrodes GE may be extended in the first direction D1 to cross the first and second channel patterns CH1 and CH2. Each of the gate electrodes GE may be overlapped with the first and second channel patterns CH1 and CH2 vertically (e.g., in the third direction D3). The gate electrode GE may include a first portion PO1 interposed between the active pattern AP1 or AP2 and the first semiconductor pattern SP1, a second portion PO2 interposed between the first semiconductor pattern SP1 and the second semiconductor pattern SP2, a third portion PO3 interposed between the second semiconductor pattern SP2 and the third semiconductor pattern SP3, and a fourth portion PO4 on the third semiconductor pattern SP3.

Referring to FIG. 7D, the gate electrode GE may be provided on a top surface TS, a bottom surface BS, and opposite side surfaces SW of each of the first to the third semiconductor patterns SP1, SP2, and SP3. A transistor according to the present embodiment may be a three-dimensional field-effect transistor (e.g., MBCFET or GAAFET), in which the gate electrode GE is provided to three-dimensionally surround the channel pattern.

A pair of the gate spacers GS may be disposed on opposite side surfaces, respectively, of the fourth portion PO4 of the gate electrode GE. The gate spacers GS may be extended along the gate electrode GE and in the first direction D1. The gate spacers GS may be extended to opposite side surfaces of a gate capping pattern GP. Top surfaces of the gate spacers GS may be higher than a top surface of the gate electrode GE. The top surfaces of the gate spacers GS may be coplanar with a top surface of a first interlayer insulating layer 1110, which will be described below. In an embodiment, the gate spacers GS may be formed of or include at least one of SiCN, SiCON, or SiN. In an embodiment, the gate spacers GS may have a multi-layered structure including at least two layers, each of which is made of SiCN, SiCON, or SiN.

The gate capping pattern GP may be provided on the gate electrode GE. The gate capping pattern GP may be extended along the gate electrode GE and in the first direction D1. The gate capping pattern GP may be formed of or include a material having an etch selectivity with respect to first and second interlayer insulating layers 110 and 120, which will be described below. In detail, the gate capping pattern GP may be formed of or include at least one of SiON, SiCN, SiCON, or SiN.

A gate insulating layer GI may be interposed between the gate electrode GE and the first channel pattern CH1 and between the gate electrode GE and the second channel pattern CH2. The gate insulating layer GI may cover the top surface TS, the bottom surface BS, and the opposite side surfaces SW of each of the first to the third semiconductor patterns SP1, SP2, and SP3. The gate insulating layer GI may cover a top surface of the device isolation layer ST below the gate electrode GE. The gate insulating layer GI may be extended into a region between the gate electrode GE and the gate spacers GS.

Referring back to FIGS. 6 and 7A to 7D, the gate electrode GE may include a first metal pattern and a second metal pattern on the first metal pattern. The first metal pattern may be provided on the gate insulating layer GI and adjacent to the first to the third semiconductor patterns SP1, SP2, and SP3. The first metal pattern may include a preferred work-function metal, which can be used to adjust a threshold voltage of the transistor. By adjusting a thickness and composition of the first metal pattern, it may be possible to realize a transistor having a desired threshold voltage. For example, the first to the third portions PO1, PO2, and PO3 of the gate electrode GE may be composed of the first metal pattern, which is the work function metal.

The first metal pattern may include a metal nitride layer. For example, the first metal pattern may include a layer that is composed of at least one metallic material, which is selected from the group consisting of titanium (Ti), tantalum (Ta), aluminum (Al), tungsten (W) and molybdenum (Mo), and nitrogen (N). In an embodiment, the first metal pattern may further include carbon (C). The first metal pattern may include a plurality of work function metal layers stacked.

The second metal pattern may include a metal whose resistance is lower than the first metal pattern. For example, the second metal pattern may include at least one metallic material, which is selected from the group consisting of tungsten (W), aluminum (Al), titanium (Ti), and tantalum (Ta). In an embodiment, the fourth portion PO4 of the gate electrode GE may include the first metal pattern and the second metal pattern on the first metal pattern.

A first interlayer insulating layer 1110 may be provided on the substrate 1100. The first interlayer insulating layer 1110 may cover the gate spacers GS and the first and second source/drain patterns SD1 and SD2. A top surface of the first interlayer insulating layer 1110 may be substantially coplanar with a top surface of the gate capping pattern GP and a top surface of the gate spacer GS.

A second interlayer insulating layer 1120 may be disposed on the first interlayer insulating layer 1110 to cover the gate capping pattern GP. A first via insulating layer 1131 may be provided on the second interlayer insulating layer 1120. A first interconnection insulating layer 1132 may be provided on the first via insulating layer 1131. A second via insulating layer 1141 may be provided on the first interconnection insulating layer 1132. A second interconnection insulating layer 1142 may be provided on the second via insulating layer 1141. In an embodiment, the first and second interlayer insulating layers 1110 and 1120, the first and second via insulating layers 1131 and 1141, and the first and second interconnection insulating layers 1132 and 1142 may include a silicon oxide layer.

The single height cell SHC may have a first border BD1 and a second border BD2, which are opposite to each other in the second direction D2. The first and second borders BD1 and BD2 may be extended in the first direction D1. The single height cell SHC may have a third border BD3 and a fourth border BD4, which are opposite to each other in the first direction D1. The third and the fourth borders BD3 and BD4 may be extended in the second direction D2.

A pair of division structures DB, which are opposite to each other in the second direction D2, may be provided at both sides of the single height cell SHC. For example, the pair of division structures DB may be provided on the first and second borders BD1 and BD2, respectively, of the single height cell SHC. The division structure DB may be extended in the first direction D1 and parallel to the gate electrodes GE. A pitch between the division structure DB and the gate electrode GE, which are adjacent to each other, may be equal to the first pitch.

The division structure DB may be provided to penetrate the first and second interlayer insulating layers 1110 and 1120 and may be extended into the first and second active patterns AP1 and AP2. The division structure DB may be provided to penetrate an upper portion of each of the first and second active patterns AP1 and AP2. The division structure DB may electrically separate an active region of the single height cell SHC from an active region of a neighboring cell.

Active contacts AC may be provided to penetrate the first and second interlayer insulating layers 1110 and 1120 and may be electrically connected to the first and second source/drain patterns SD1 and SD2, respectively. A pair of the active contacts AC may be respectively provided at both sides of the gate electrode GE. When viewed in a plan view, the active contact AC may be a bar-shaped pattern extending in the first direction D1.

The active contact AC may be a self-aligned contact. That is, the active contact AC may be formed in a self-aligned manner using the gate capping pattern GP and the gate spacer GS. For example, the active contact AC may cover at least a portion of a side surface of the gate spacer GS. Although not shown, the active contact AC may cover a portion of a top surface of the gate capping pattern GP.

A metal-semiconductor compound layer SC (e.g., a silicide layer) may be interposed between the active contact AC and the first source/drain pattern SD1 and between the active contact AC and the second source/drain pattern SD2. The active contacts AC may be electrically connected to the first and second source/drain patterns SD1 and SD2 through the metal-semiconductor compound layer SC. In an embodiment, the metal-semiconductor compound layer SC may be formed of or include at least one of titanium silicide, tantalum silicide, tungsten silicide, nickel silicide, and cobalt silicide.

Referring to FIG. 7B, a region, which is located on the active contact AC and is adjacent to a gate contact GC0, may be filled with an upper insulating pattern UIP. A bottom surface of the upper insulating pattern UIP may be lower than a bottom surface of the gate contact GC0. In other words, a top surface of the active contact AC adjacent to the gate contact GC0 may be lower than the bottom surface of the gate contact GC0, owing to the presence of the upper insulating pattern UIP.

The active contact AC may include a conductive pattern FM and a barrier pattern BM enclosing the conductive pattern FM. In an embodiment, the conductive pattern FM may be formed of or include at least one of metallic materials (e.g., aluminum, copper, tungsten, molybdenum, and cobalt). The barrier pattern BM may cover side and bottom surfaces of the conductive pattern FM. The barrier pattern BM may include a metal layer and a metal nitride layer. The metal layer may be formed of or include at least one of titanium, tantalum, tungsten, nickel, cobalt, or platinum. The metal nitride layer may be formed of or include at least one of titanium nitride (TIN), tantalum nitride (TaN), tungsten nitride (WN), nickel nitride (NiN), cobalt nitride (CON), or platinum nitride (PtN).

First metal lines M1 may be disposed in the first interconnection insulating layer 1132. The first metal lines M1 may be extended in the second direction D2 and parallel to each other.

First vias VI0 may be provided on the first metal lines M1. The first vias VI0 may be disposed in the first via insulating layer 1131. The active contact AC and the first metal line M1 may be electrically connected to each other through the first vias VI0. The gate contact GC0 and the first metal line M1 may be electrically connected to each other through the first via VI0. The first metal lines M1 and the first vias VI0 thereunder may be formed by separate processes.

Second metal lines M2 may be provided in the second interconnection insulating layer 1142. Each of the second metal lines M2 may be a line-shaped or bar-shaped pattern extending in the first direction D1. In other words, the second metal lines M2 may be extended in the first direction D1 and parallel to each other.

Second vias VI1 may be disposed on the second metal lines M2. The second vias VI1 may be disposed in the second via insulating layer 1141. The first and second metal lines M1 and M2 may be electrically connected to each other through the second vias VI1. As an example, the second metal lines M2 and the second vias VI1 may be formed together. Although not shown, a plurality of metal layers (e.g., M3, M4, M5, and so forth) may be additionally stacked on the second interconnection insulating layer 1142. Each of the stacked metal layers may include interconnection lines, which are used as a routing structure between cells.

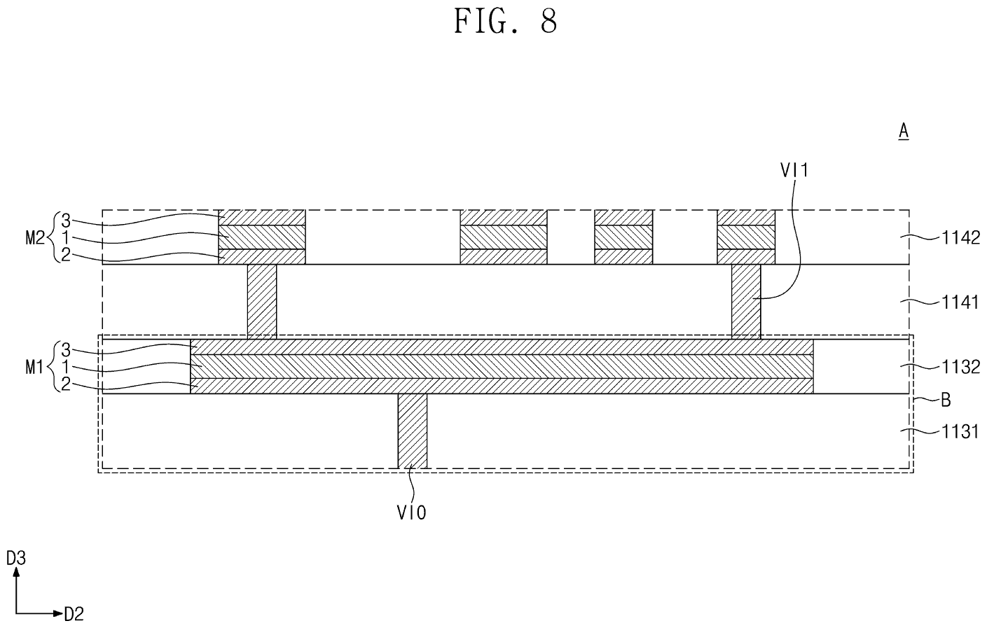

FIG. 8 is an enlarged sectional view illustrating a portion ‘A’ of FIG. 7A. Referring to FIGS. 6, 7A, and 8 in conjunction with FIGS. 3A to 3D, the first and/or second metal lines M1 and/or M2 may be one of the interconnection structures 10, 11, 12, and 13.

The barrier pattern 2 may be disposed to improve the roughness of the first and/or second metal lines M1 and/or M2, if necessary, and may be interposed between the substrate 1100 and the first interconnection line 1. The second interconnection line 3 may be disposed to improve the resistivity of the first and/or second metal lines M1 and/or M2, and the first interconnection line 1 may be interposed between the substrate 1100 and second interconnection line 3.

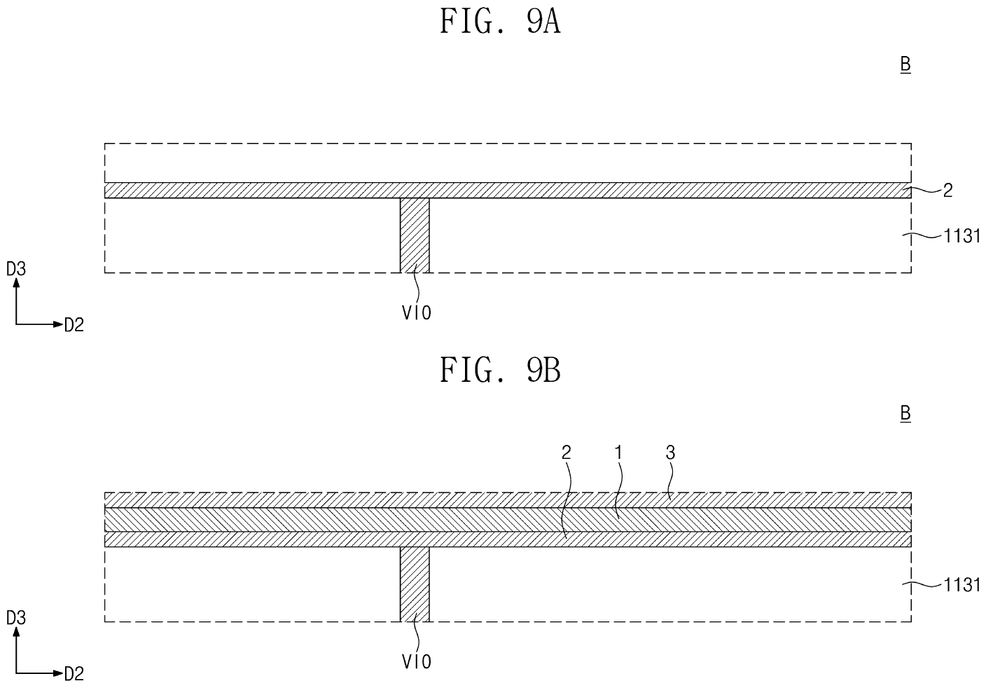

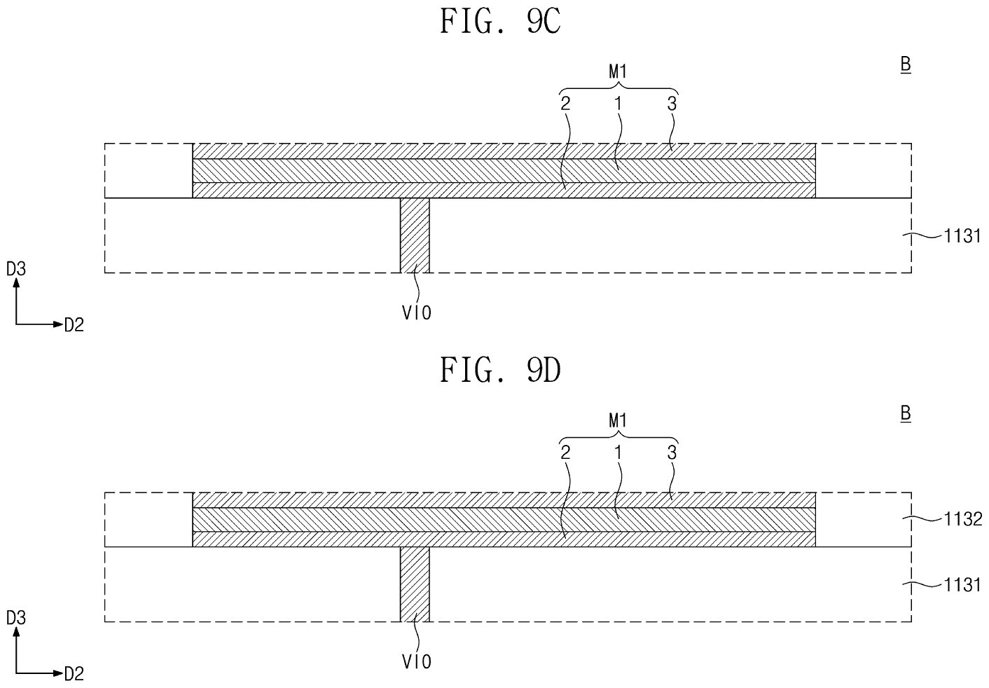

FIGS. 9A to 9D are enlarged sectional views (in particular, of a portion ‘B’ of FIG. 8) schematically illustrating a method of fabricating an interconnection structure according to an embodiment of the inventive concept. The following description will refer to a fabrication method in which the first metal lines M1 are provided to have the interconnection structure 13.

Referring to FIG. 9A, the first via VI0 may be formed in the first via insulating layer 1131, and the barrier pattern 2 may be formed on the first via insulating layer 1131. The formation of the first via VI0 in the first via insulating layer 1131 may include etching the first via insulating layer 1131 and forming the first via VI0 in the first via insulating layer 1131. The formation of the barrier pattern 2 may be performed using a physical vapor deposition (PVD) process or an atomic layer deposition (ALD) process. The formation of the barrier pattern 2 may be omitted, depending on a desired roughness value of the interconnection structure.

Referring to FIG. 9B, the first interconnection line 1 may be formed on the first via insulating layer 1131, and the second interconnection line 3 may be formed on the first via insulating layer 1131. The first interconnection line 1 may cover a top surface of the barrier pattern 2. The second interconnection line 3 may cover a top surface of the first interconnection line 1. The formation of the first interconnection line 1 and the formation of the second interconnection line 3 may be performed using a physical vapor deposition (PVD) process or an atomic layer deposition (ALD) process. The formation of the second interconnection line 3 may be omitted, depending on a desired resistivity value of the final interconnection structure.

Referring to FIG. 9C, the first metal lines M1 may be formed. The formation of the first metal lines M1 may include etching a portion of the second interconnection line 3, etching a portion of the first interconnection line 1, and etching a portion of the barrier pattern 2. The partial etching of the first and second interconnection lines 1 and 3 and the barrier pattern 2 may be performed using a dry etching process. The barrier pattern 2, the first interconnection line 1, and the second interconnection line 3 may have substantially the same length in the second direction D2.

Referring to FIG. 9D, the first interconnection insulating layer 1132 may be formed on the first via insulating layer 1131. The first interconnection insulating layer 1132 may cover a portion of a top surface of the first via insulating layer 1131 and side surfaces of the first metal lines M1. The first interconnection insulating layer 1132 may expose the first metal lines M1. An annealing process may be performed after the formation of the first interconnection insulating layer 1132.

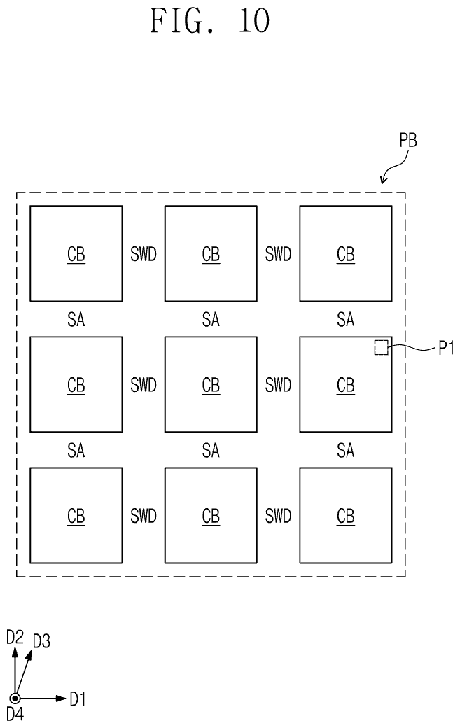

FIG. 10 is a block diagram illustrating a semiconductor memory device according to an embodiment of the inventive concept. Referring to FIG. 10, a semiconductor memory device 2000 may include cell blocks CB and a peripheral block PB enclosing each of the cell blocks CB. Each of the cell blocks CB may include a cell circuit (e.g., a memory integrated circuit). The peripheral block PB may include various peripheral circuits, which are used to operate the cell circuit, and the peripheral circuits may be electrically connected to the cell circuit.

The peripheral block PB may include sense amplifier circuits SA and sub-word line driver circuits SWD. In an embodiment, the sense amplifier circuits SA may be provided to face each other, with the cell blocks CB interposed therebetween, and the sub-word line driver circuits SWD may be provided to face each other, with the cell blocks CB interposed therebetween. The peripheral block PB may further include power and ground driver circuits for driving a sense amplifier, but the inventive concept is not limited to this example.

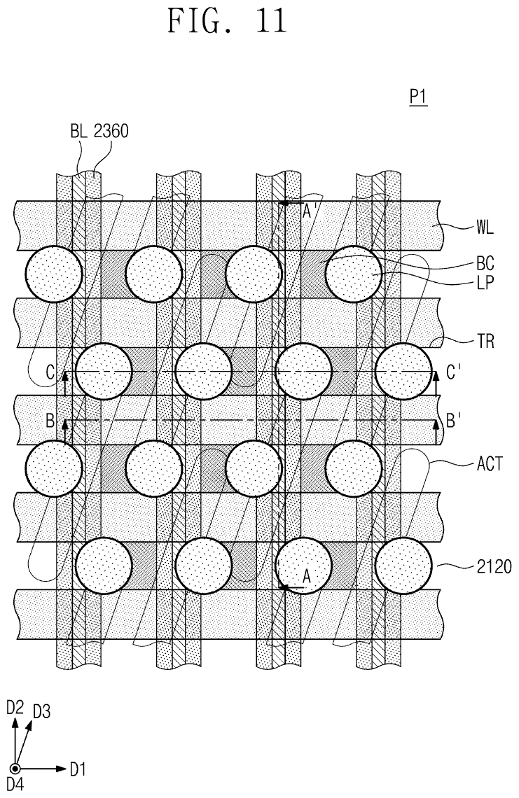

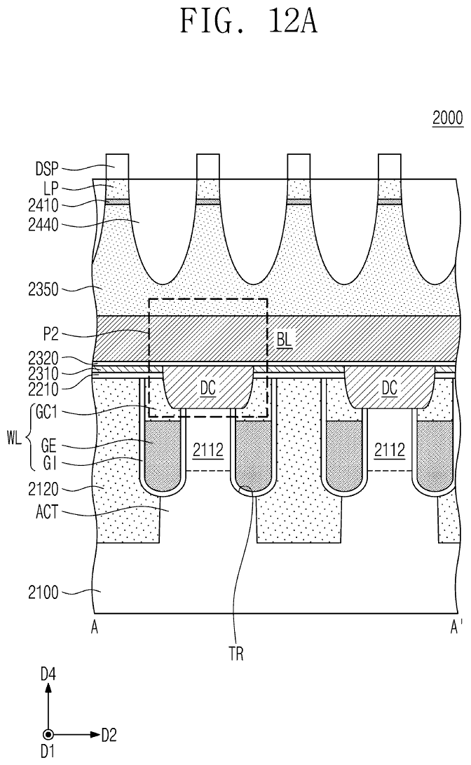

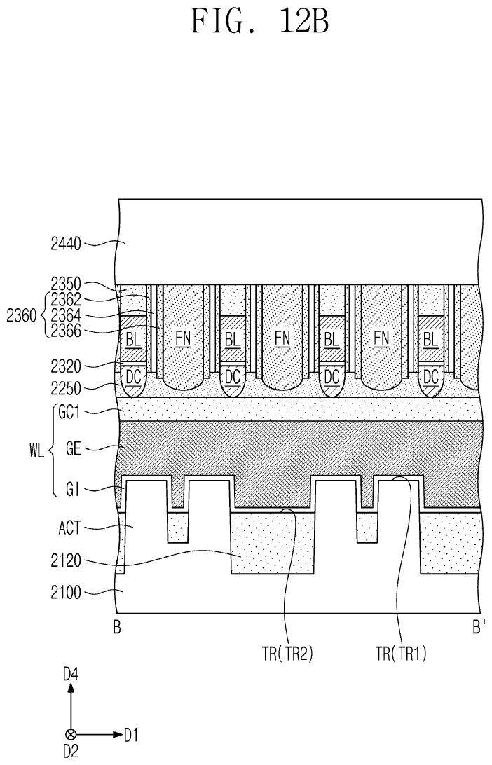

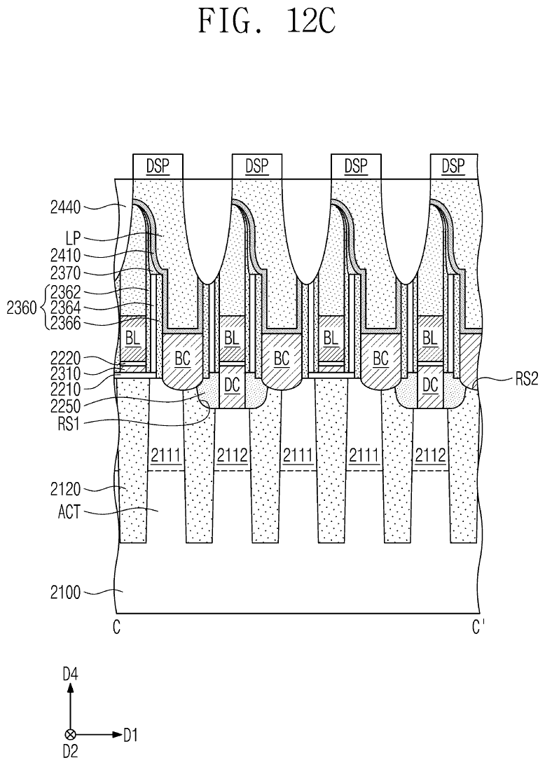

FIG. 11 is a plan view illustrating a semiconductor memory device according to an embodiment of the inventive concept and corresponding to a portion ‘P1’ of FIG. 10. FIG. 12A is a sectional view, which is taken along a line A-A′ of FIG. 11 to illustrate a semiconductor memory device according to an embodiment of the inventive concept. FIG. 12B is a sectional view, which is taken along a line B-B′ of FIG. 11 to illustrate a semiconductor memory device according to an embodiment of the inventive concept. FIG. 12C is a sectional view, which is taken along a line C-C′ of FIG. 11 to illustrate a semiconductor memory device according to an embodiment of the inventive concept.

Referring to FIGS. 11, 12A, 12B, and 12C, a substrate 2100 may be provided. The substrate 2100 may be a semiconductor substrate (e.g., a silicon substrate, a germanium substrate, or a silicon-germanium substrate). A device isolation pattern 2120 may be disposed on the substrate 2100 to define active patterns ACT. The active patterns ACT may be provided on the cell blocks CB of FIG. 1. The active patterns ACT may be spaced apart from each other in the first and second directions D1 and D2, which are non-parallel (e.g., orthogonal) to each other. The first and second directions D1 and D2 may be parallel to a bottom surface of the substrate 2100. The active patterns ACT may be isolated bar-shaped patterns, which are spaced apart from each other and are elongated in the third direction D3. The third direction D3 may be parallel to the bottom surface of the substrate 2100 and may not be parallel to the first and second directions D1 and D2.

The active patterns ACT may have a shape protruding in a fourth direction D4 perpendicular to the bottom surface of the substrate 2100. For example, the device isolation pattern 2120 may be disposed in the substrate 2100, and the active patterns ACT may be portions of the substrate 2100 surrounded by the device isolation pattern 2120. For the sake of convenience in explanation, the term “substrate 2100” may refer to the remaining portion of the substrate 2100, excluding the active patterns ACT, unless otherwise stated.

The device isolation pattern 2120 may include an insulating material and may be formed of or include at least one of silicon oxide, silicon nitride, or combinations thereof. The device isolation pattern 2120 may be a single layer, which is made of a single material, or a composite layer including two or more materials.

A word line WL may be disposed to cross the active patterns ACT. As an example, the word line WL may cross the active patterns ACT and the device isolation pattern 2120 in the first direction D1. In an embodiment, a plurality of word lines WL may be provided. The word lines WL may be spaced apart from each other in the second direction D2. In an embodiment, a pair of word lines WL, which are adjacent to each other in the second direction D2, may be provided to cross the active pattern ACT.

The word line WL may be disposed in a trench region TR crossing the active patterns ACT and the device isolation pattern 2120. The trench region TR may be extended in the first direction D1. Each of the word lines WL may include the gate electrode GE, a gate insulating pattern GI, and a gate capping pattern GC1. The gate electrode GE may cross the active pattern ACT and the device isolation pattern 2120 in the first direction D1. The gate insulating pattern GI may be interposed between the gate electrode GE and the active patterns ACT and between the gate electrode GE and the device isolation pattern 2120. The gate capping pattern GC1 may be provided on the gate electrode GE to cover the top surface of the gate electrode GE.

A buffer pattern 2210 may be disposed on the substrate 2100. The buffer pattern 2210 may cover the active patterns ACT, the device isolation pattern 2120, and the word lines WL. In an embodiment, the buffer pattern 2210 may be formed of or include at least one of silicon oxide, silicon nitride, silicon oxynitride, or combinations thereof. The buffer pattern 2210 may be a single layer, which is made of a single material, or a composite layer including two or more materials.

A bit line contact DC may be provided on each of the active patterns ACT, and in an embodiment, a plurality of bit line contacts DC may be provided. The bit line contacts DC may be connected to center portions 2112 of the active patterns ACT, respectively. The bit line contacts DC may be spaced apart from each other in the first and second directions D1 and D2. The bit line contact DC may be interposed between each of the active patterns ACT and a corresponding one of bit lines BL, which will be described below. The bit line contacts DC may connect a corresponding one of the bit lines BL to the center portion 112 of a corresponding one of the active patterns ACT.

The bit line BL may be provided on the bit line contact DC. The bit line BL may be extended in the second direction D2. The bit line BL may be disposed on the bit line contacts DC, which are arranged in the second direction D2 to form a line. In an embodiment, a plurality of bit lines BL may be provided. The bit lines BL may be spaced apart from each other in the first direction D1. The bit line BL will be described in more detail with reference to FIG. 15.

A polysilicon pattern 2310 may be provided between the bit line BL and the buffer pattern 2210 and between the bit line contacts DC, which are adjacent to each other in the second direction D2. In an embodiment, a plurality of polysilicon patterns 2310 may be provided. In an embodiment, the polysilicon pattern 2310 may be spaced apart from each other in the first and second directions D1 and D2. A top surface of the polysilicon pattern 2310 may be located at substantially the same height as a top surface of the bit line contact DC and may be coplanar with the top surface of the bit line contact DC. The polysilicon pattern 2310 may be formed of or include doped polysilicon.

An ohmic pattern 2320 may be provided between the bit line BL and the bit line contact DC and between the bit line BL and the polysilicon pattern 2310. The ohmic pattern 2320 may be extended along the bit lines BL and in the second direction D2. The ohmic pattern 2320 may be formed of or include metal silicide.

A bit line capping pattern 2350 may be provided on a top surface of the bit line BL. On the top surface of the bit line BL, the bit line capping pattern 2350 may be extended in the second direction D2. In an embodiment, a plurality of bit line capping patterns 2350 may be provided. The bit line capping patterns 2350 may be spaced apart from each other in the first direction D1. The bit line capping pattern 2350 may be vertically overlapped with the bit line BL. The bit line capping pattern 2350 may be composed of a single layer or a plurality of layers.

A bit line spacer 2360 may be provided on a side surface of the bit line BL and a side surface of the bit line capping pattern 2350. The bit line spacer 2360 may cover the side surface of the bit line BL and the side surface of the bit line capping pattern 2350. On the side surface of the bit line BL, the bit line spacer 2360 may be extended in the second direction D2. In an embodiment, a plurality of bit line spacers 2360 may be provided. The bit line spacers 2360 may be spaced apart from each other in the first direction D1.

A storage node contact BC may be provided between adjacent ones of the bit lines BL. As an example, the storage node contact BC may be interposed between adjacent ones of the bit line spacers 360. In an embodiment, a plurality of storage node contacts BC may be provided. The storage node contacts BC may be spaced apart from each other in the first and second directions D1 and D2. The storage node contacts BC may be spaced apart from each other in the second direction D2 by fence patterns FN on the word lines WL. The fence pattern FN may be provided between adjacent ones of the bit lines BL. In an embodiment, a plurality of fence patterns FN may be provided. The fence patterns FN may be spaced apart from each other in the first and second directions D1 and D2. The fence patterns FN, which are adjacent to each other in the first direction D1, may be spaced apart from each other, with the bit line BL interposed therebetween. The fence patterns FN, which are adjacent to each other in the second direction D2, may be spaced apart from each other with the storage node contact BC interposed therebetween. In an embodiment, the fence patterns FN may be formed of or include silicon nitride.

The storage node contact BC may fill a second recess region RS2, which is provided on an edge portion 111 of the active pattern ACT. The storage node contact BC may be connected to the edge portion 111. The storage node contact BC may be formed of or include at least one of doped or undoped polysilicon, metallic materials, or combinations thereof.

A second barrier pattern 2410 may conformally cover the bit line spacer 2360, the fence pattern FN, and the storage node contact BC. The second barrier pattern 2410 may include metal nitride materials (e.g., titanium nitride and tantalum nitride). A landing pad LP may be provided on the storage node contact BC. In an embodiment, a plurality of landing pads LP may be provided. The landing pads LP may be spaced apart from each other in the first and second directions D1 and D2. Each of the landing pads LP may be connected to a corresponding one of the storage node contacts BC. The landing pad LP may cover a top surface of the bit line capping pattern 2350. A lower region of the landing pad LP may be vertically overlapped with the storage node contact BC. An upper region of the landing pad LP may be shifted from the lower region in the first direction D1. The landing pad LP may be formed of or include at least one of metallic materials (e.g., tungsten, titanium, and tantalum).

A filler pattern 2440 may be provided to enclose the landing pad LP. The filler pattern 2440 may be interposed between the landing pads LP, which are adjacent to each other. When viewed in a plan view, the filler pattern 2440 may have a mesh-shaped pattern including holes, in which the landing pads LP are disposed. In an embodiment, the filler pattern 2440 may include at least one of silicon nitride, silicon oxide, silicon oxynitride, or combinations thereof. In another embodiment, the filler pattern 2440 may include an empty space (i.e., an air gap) including an air layer.

A data storage pattern DSP may be provided on the landing pad LP. In an embodiment, a plurality of data storage patterns DSP may be provided. The data storage patterns DSP may be spaced apart from each other in the first and second directions D1 and D2.

In an embodiment, the data storage pattern DSP may be a capacitor including a bottom electrode, a dielectric layer, and a top electrode. In this case, the semiconductor memory device may be a dynamic random access memory (DRAM) device. In an embodiment, the data storage pattern DSP may include a magnetic tunnel junction pattern. In this case, the semiconductor memory device may be a magnetic random access memory (MRAM) device. In an embodiment, the data storage pattern DSP may be formed of or include a phase-change material or a variable resistance material. In this case, the semiconductor memory device may be a phase-change random access memory (PRAM) device or a resistive random access memory (ReRAM) device. However, the inventive concept is not limited to these examples, and the data storage pattern DSP may include various structures and/or materials which can be used to store data.

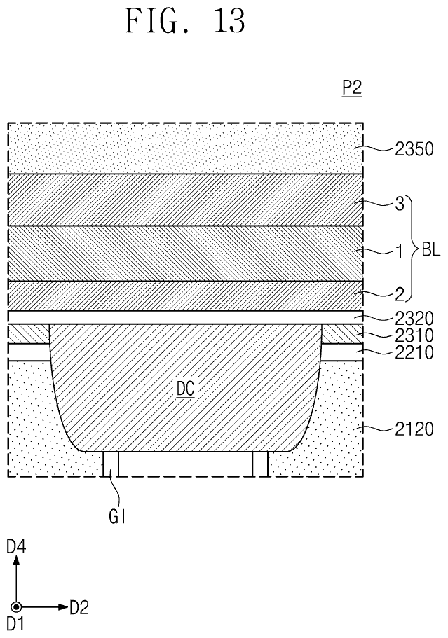

FIG. 13 is an enlarged view illustrating a portion ‘P2’ of FIG. 12A. Referring to FIGS. 11, 12A, 12B, 12C, and 13 in conjunction with FIGS. 3A to 3D, the bit line BL may be the interconnection structure 13. Alternatively, the bit line BL may be one of the interconnection structures 10, 11, and 12.

The barrier pattern 2 may be disposed to improve the roughness of the first and/or second metal lines M1 and/or M2, if necessary, and may be interposed between the substrate 2100 and the first interconnection line 1. The second interconnection line 3 may be disposed to improve the resistivity of the first and/or second metal lines M1 and/or M2, if necessary, and the first interconnection line 1 may be interposed between the substrate 2100 and the second interconnection line 3.

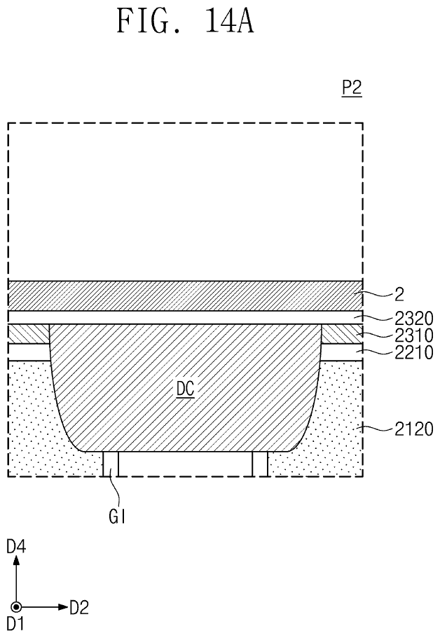

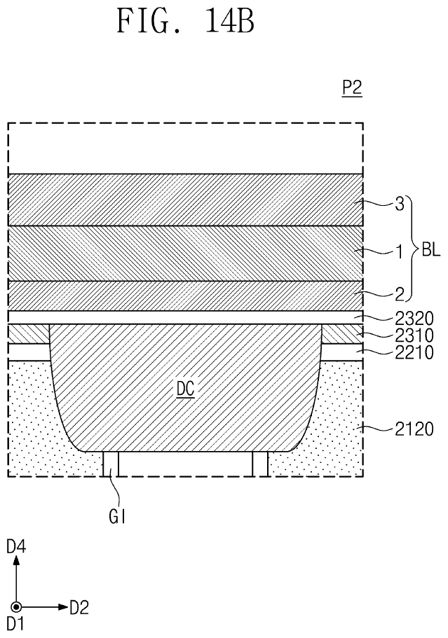

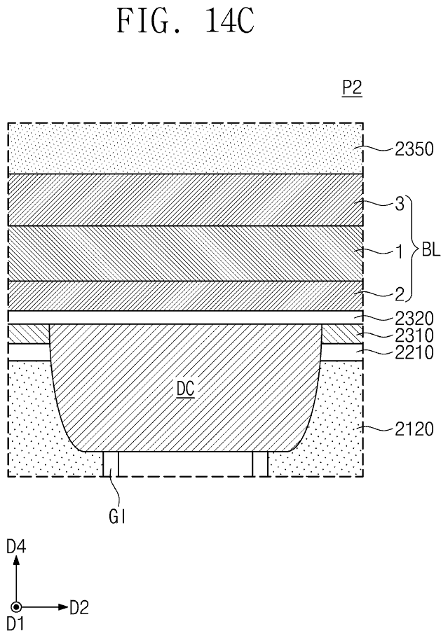

FIGS. 14A to 14C are diagrams schematically illustrating a method of fabricating an interconnection structure, according to an embodiment of the inventive concept. Referring to FIG. 14A, the ohmic pattern 2320 may be formed on the bit line contact DC, and the barrier pattern 2 may be formed on the bit line contact DC. The formation of the barrier pattern 2 may be formed through a physical vapor deposition (PVD) process or an atomic layer deposition (ALD) process. The formation of the barrier pattern 2 may be omitted, depending on a desired roughness of the final interconnection structure.

Referring to FIG. 14B, the bit line BL (e.g., the interconnection structure 10, 11, 12, or 13) may be formed on the bit line contact DC. The first interconnection line 1 may be formed on the bit line contact DC, and the second interconnection line 3 may be formed on the bit line contact DC. The first interconnection line 1 may cover a top surface of the barrier pattern 2. The second interconnection line 3 may cover the top surface of the first interconnection line 1. The first and second interconnection lines 1 and 3 may be formed by a physical vapor deposition (PVD) process or an atomic layer deposition (ALD) process. The formation of the second interconnection line 3 may be omitted, depending on a desired resistivity value of the final interconnection structure.

Referring to FIG. 14C, the bit line capping pattern 2350 may be formed on the bit line BL.

Example embodiments described herein include semiconductor devices applied to typical logic and memory (DRAM) products, but the inventive concept is not limited to these examples. For example, the semiconductor device may be a 3-stacked CMOS image sensor (CIS) chip, a vertical NAND memory device, a bonding vertical NAND memory device, in which upper and lower plates serving as cell and peripheral regions are bonded to each other by a wafer bonding method, a 3D DRAM device, or a back side power delivery network (BSPDN) structure, in which a backside surface of an integrated circuit layer is thinned.

In a semiconductor device according to an embodiment of the inventive concept, a metallic material, which has low resistivity and small roughness even in a thin region, may be used to form an interconnection structure and/or a via structure. In this case, it may be possible to improve reliability of the interconnection structure, the via structure, and/or the semiconductor device and to prevent a process failure (e.g., a line open issue) from occurring in the interconnection structure and/or the via structure.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a substrate; and
an interconnection layer on the substrate, said interconnection layer comprising an interconnection structure having a first interconnection line therein that comprises a metal alloy containing a single phase of ruthenium and a non-ruthenium first element having a concentration in a range from greater than 0 at % to 40 at % in the metal alloy.

2. The device of claim 1, wherein the first element is molybdenum, and the concentration of the first element in the metal alloy ranges from 0.1 at % to 30 at %.

3. The device of claim 1, wherein the first element is tungsten, and the concentration of the first element in the metal alloy ranges from 0.1 at % to 40 at %.

4. The device of claim 1, wherein the concentration of the first element in the metal alloy ranges from 0.1 at % to 12 at %.

5. The device of claim 1, wherein one of a linewidth and a thickness of the first interconnection line is less than or equal to 30 nm.

6. The device of claim 1, wherein one of a linewidth and a thickness of the first interconnection line ranges from 0.1 nm to 10 nm.

7. The device of claim 1, wherein the interconnection structure further comprises a barrier pattern extending between the first interconnection line and the substrate; and wherein the barrier pattern includes at least one of metal, metal nitride, or metal silicide.

8. The device of claim 7, wherein a thickness of the barrier pattern ranges from 0.1 nm to 5 nm.

9. The device of claim 7, wherein a thickness of the barrier pattern is less than a thickness of the first interconnection line.

10. The device of claim 1,
wherein the interconnection structure further comprises a second interconnection line extending on the first interconnection line;
wherein the second interconnection line is in contact with the first interconnection line;
wherein the first interconnection line extends between the substrate and the second interconnection line;
wherein the second interconnection line comprises ruthenium (Ru); and
wherein a concentration of ruthenium in the second interconnection line is greater than a concentration of ruthenium in the first interconnection line.

11. The device of claim 10, wherein the concentration of ruthenium in the second interconnection line is greater than or equal to 99 at %.

12. The device of claim 10, wherein a thickness of the interconnection structure is less than 200 nm.

13. The device of claim 10, wherein a thickness of the interconnection structure ranges from 1 nm to 40 nm.

14. The device of claim 1, wherein the substrate has regions of a transistor therein; wherein the transistor comprises a gate electrode on the substrate and a source/drain region within the substrate; wherein the interconnection layer further comprises a gate contact, which is in electrical contact with the gate electrode, and an active contact, which is in electrical contact with the source/drain region; and wherein the interconnection structure is in electrical contact with each of the gate contact and the active contact.

15. The device of claim 1, wherein the substrate has regions of a transistor therein; wherein the transistor comprises a first source/drain region and a second source/drain region within the substrate; wherein the semiconductor device further comprises a capacitor, which is electrically connected to the first source/drain region; and wherein the interconnection structure is electrically connected to the second source/drain region.

16. The device of claim 15, wherein the transistor further comprises a bit line contact in contact with the second source/drain region and the interconnection structure; and wherein the bit line contact extends between the second source/drain region and the interconnection structure.

17. A semiconductor device, comprising:
a substrate including a transistor; and
an interconnection layer disposed on the substrate;
wherein the interconnection layer comprises:
an interconnection structure; and
a first via on the interconnection structure;
wherein the interconnection structure includes a first interconnection line, which comprises ruthenium and a first metal alloy, which contains a first element different from the ruthenium;
wherein a composition ratio of the first element in the first metal alloy is greater than 0 at % and less than 40 at %; and
wherein the first metal alloy has a single phase of the ruthenium.

18. The device of claim 17, wherein the first via comprises ruthenium and a second metal alloy, which contains a first element different from the ruthenium; wherein a composition ratio of the first element in the second metal alloy is greater than 0 at % and less than 40 at %; and wherein the second metal alloy has a single phase of the ruthenium.

19. The device of claim 17, wherein a minimum value of a diameter of the first via ranges from 0.1 nm to 30 nm.

20. A semiconductor device, comprising:
a substrate including a transistor; and
an interconnection layer extending on the substrate;
wherein the interconnection layer comprises an interconnection structure including a plurality of first interconnection lines;
wherein each of the first interconnection lines extends in a first direction parallel to the substrate;
wherein the first interconnection lines comprise interconnection lines, which have a pitch ranging from 1 nm to 60 nm in a second direction that is parallel to the substrate and is perpendicular to the first direction;
wherein the first interconnection lines comprise ruthenium and a metal alloy, which contains a first element different from the ruthenium;
wherein a composition ratio of the first element in the metal alloy is greater than 0 at % and less than 40 at %; and
wherein the metal alloy has a single phase of the ruthenium.
